(19) United States
(12) Patent Application Publication
(10) Pub. No.: US 2026/0133235 A1
(43) Pub. Date: May 14, 2026

(54) JOINT FAULT DETECTION AND COMMUNICATION FOR DC POWER LINES

(71) Applicant: Cence Power Inc., Markham (CA)

(72) Inventors: Milad JOHNNY, Thornhill (CA); Mohammad BALASMEH, Newmarket (CA); Bolis IBRAHIM, Richmond Hill (CA); Sagar JAISWAL, Milton (CA)

(73) Assignee: Cence Power Inc., Markham (CA)

(21) Appl. No.: 18/941,583

(22) Filed: Nov. 8, 2024

(51) Int. Cl. G01R 31/08; G01R 31/11

(52) U.S. Cl. CPC G01R 31/085; G01R 31/11

(57) ABSTRACT

A fault detection system and method for detecting a fault condition in a direct current (DC) system. A power transmitter energizes a cable with electrical power. A power receiver connected to the cable provides the electrical power to a load. At the power receiver, a signal generator coupled to the cable generates and propagates a deterministic signal on the cable. At the power transmitter, a fault detector is coupled to the cable to receive the deterministic signal and noise after propagation through the cable. The fault detector has a plurality of filter branches with each of the filter branches having an associated bandwidth. Adjusting a gain of one or more of the filter branches in response to a signal-to-noise ratio of the cable. The cable is deenergized when a fault is detected on at least one of the filter branches.

### FIELD

The present application generally relates to direct current (DC) power lines and, in particular, to methods and systems for fault detection on high voltage DC power lines.

### BACKGROUND

High voltage power lines can be dangerous. DC can be a desirable option for power transmission in some cases to minimize alternating current (AC) line losses and to minimize AC-DC conversions in the case of DC loads. DC can be dangerous in that it does not have zero-crossings that can serve to self-extinguish an arc. To safely transmit high voltage DC power, a very high-speed fault detection mechanism is needed. For example, in a 450V rated system a clearing time for low resistance ground faults is about 5.4 milliseconds.

DC power transmission can be implemented as a two-wire system or a three-wire system. Faults can be human contact (one wire touch, or two wire touch), short circuit, open circuit, over voltage, or over current. Human contact can be dangerous and sometimes even fatal. Fast fault detection and power disconnection are a safety feature.

### BRIEF DESCRIPTION OF THE DRAWINGS

Reference will now be made, by way of example, to the accompanying drawings which show example embodiments of the present application, and in which:

FIG. 1A diagrammatically illustrates an example of a basic DC power two-wire transmission system;

FIG. 1B diagrammatically shows an example of a three-wire DC transmission system;

FIG. 2 shows one simplified example fault detection system for DC power transmission;

FIG. 3 shows a simplified diagram of a signal generator providing a signal to the DC power transmission line for fault detection;

FIG. 4 shows a simplified diagram of an example system for detecting a fault on a transmission line;

FIGS. 5 and 6 show a multiple branch detection system for detecting a fault on the transmission line; and

FIG. 7 shows a water filling technique for multiple branches of the detection system.

Similar reference numerals may have been used in different figures to denote similar components.

### DETAILED DESCRIPTION

In an aspect, the present application describes a fault detection system for detecting a fault condition in a direct current (DC) system. The system may include a power transmitter including a DC source to energize a cable and a power receiver connected to the transmission line to couple the cable to a load. At the power receiver the system may include a signal generator coupled to the cable to generate and propagate a periodic signal on the cable, and at the power transmitter the system may include a power detector coupled to the cable to receive the signal after propagation through the cable and to output a power signal proportional to root-mean-square (RMS) power of the periodic signal, a differentiator to receive the power signal and to produce a power rate-of-change signal, and a fault detection circuit to output a fault signal based on the power rate-of-change signal.

According to one aspect, there is provided a fault detection system for detecting a fault condition in a direct current (DC) system. The system may comprise: a power transmitter to energize a cable with electrical power; a power receiver connected to the cable providing the electrical power to a load; and at the power receiver, a signal generator coupled to the cable to generate and propagate a deterministic signal on the cable. At the power transmitter, a fault detector coupled to the cable to receive the deterministic signal and noise after propagation through the cable. The fault detector may comprise a plurality of filter branches, the filter branches having an associated bandwidth filtering the received signal. The associated bandwidth of one of the filter branches may provide a reaction time to detect the fault within a predetermined time. The associated bandwidth of another of the filter branches may reduce susceptibility to the noise. A disconnection circuitry discharging the cable when a fault is detected on at least one of the filter branches.

The signal generator may comprise a pseudorandom number sequence generator and the deterministic signal comprises at least a pseudorandom number sequence. The pseudorandom number sequence may be selected from: a Barker code, a binary Alexis sequence, a Gold code, and a Kasami code. The signal generator may comprise a synchronization code generator adding a synchronization code to the deterministic signal. The signal generator may comprise a modulator modulating a carrier signal with the deterministic signal. The fault detector may comprise a phase-locked loop to lock onto the carrier signal. The fault may be detected based on a summation of an output of the filter branches. A processor may be configured to adjust one or more weights (or even all the weights) for the one or more filter branches. The weights may be adjusted based at least in part on a signal to noise ratio at an input of the fault detector. In some aspects, the deterministic signal may be produced by a sinusoidal generator and the deterministic signal may be a sinusoid at a frequency.

According to another aspect, there is provided a fault detection method for detecting a fault condition in a direct current (DC) system. The method may comprise: energizing a cable from a power transmitter to a power receiver; providing electrical power to a load; generating and propagating a deterministic signal on the cable from the power receiver to the power transmitter; receiving a received signal comprising the deterministic signal and noise at the power transmitter and passing the received signal through a plurality of filter branches, the filter branches having an associated bandwidth filtering the received signal; detecting a fault from at least one of the filter branches; and discharging the cable when the fault is detected.

The generating of the deterministic signal may comprise at least a pseudorandom number sequence. The pseudorandom number sequence may be selected from: a Barker code, a binary Alexis sequence, a Gold code, and a Kasami code. The generating of the deterministic signal may comprise adding a synchronization code to the deterministic signal. The generating of the deterministic signal may comprise modulating a carrier signal with the deterministic signal.

The fault detection method may lock onto the carrier signal with a phase-locked loop at the power transmitter.

The fault detection method may further sum an output of the filter branches to detect the fault. At least one of the filter branches may track fault events in a rapid manner.

The method may adjust at least one weight on at least one of the filter branches. The adjusting of the weights may be based on at least a signal-to-noise ratio of the received signal.

Other aspects and features of the present application will be understood by those of ordinary skill in the art from a review of the following description of examples in conjunction with the accompanying figures.

In the present application, the terms “about”, “approximately”, and “substantially” are meant to cover variations that may exist in the upper and lower limits of the ranges of values, such as variations in properties, parameters, and dimensions. In a non-limiting example, the terms “about”, “approximately”, and “substantially” may mean plus or minus 10 percent or less.

In the present application, the term “and/or” is intended to cover any possible combinations and sub-combinations of the listed elements, including any one of the listed elements alone, any sub-combination, or any of the elements, and without necessarily excluding additional elements.

In the present application, the phrase “at least one of . . . or . . . ” is intended to cover any one or more of the listed elements, including any one of the listed elements alone, any sub-combination, or all the elements, without necessarily excluding any additional elements, and without necessarily requiring all the elements.

The present application relates to fault detection for power lines and, in particular, fault detection for DC power lines.

In this application, the term “high voltage” is intended to include any voltage that is unsafe to humans or may cause harm to the surrounding environment. This may include, for example, class 4 power lines.

A human touch fault may be modeled as a high resistance ground fault (HRGF) in some cases. A fault detection system ideally quickly detects the occurrence of this condition and disconnects power from the transmission line as a result. The time between contact and power shut off may be within the range of 3.78 milliseconds to 5.59 seconds for a corresponding current of 990 mA to 6 mA respectively. In other aspects, the time between fault and power shut off may be based on one or more standards, such as UL 943 standard relating to ground-fault circuit interrupters, IEC 60479-1 as per UL 1400-1, or other such standards. In some aspects, the reaction time may depend at least in part on the current passing through the fault.

A human body impedance model may be used in assessing capacitance-sensing based active injury mitigation systems. The characteristic impedance of a human body varies with frequency. At low frequencies (up to a few kHz), the impedance of the human body is primarily resistive, meaning it behaves like a simple resistor. This resistance is mainly due to the electrical resistance of tissues and fluids in the body. As the frequency increases into the radio frequency (RF) range (from a few kHz to several GHz), the impedance of the human body starts to exhibit capacitive and inductive components in addition to the resistive component. The impedance of the human body also varies depending on factors such as the body's size, level of hydration/moisture, and the frequency range of interest. In practical terms, this means that the human body can interact differently with electromagnetic fields at different frequencies, influencing factors such as signal transmission through cables or antennas, as well as the absorption of electromagnetic radiation.

In the present application, the term “cable” may be used to refer to a two-wire or three-wire conductor for DC power transmission. The term “cable” is intended to encompass all suitable conductors for DC power transmission and as will be described below, in some cases may be modeled or treated as a long-wire antenna or may be modeled or treated as a transmission line. The term “transmission line” may be referred to below when describing a connection between a DC power transmitter and a DC power receiver but that term should not necessarily be understood to mean in all cases that the connection is treated as a transmission line model, e.g. balanced positive and negative lines and a traveling sinusoidal signal having a reference to ground. In some cases, the described cable or transmission line may conform to an antenna model having an unbalanced signal.

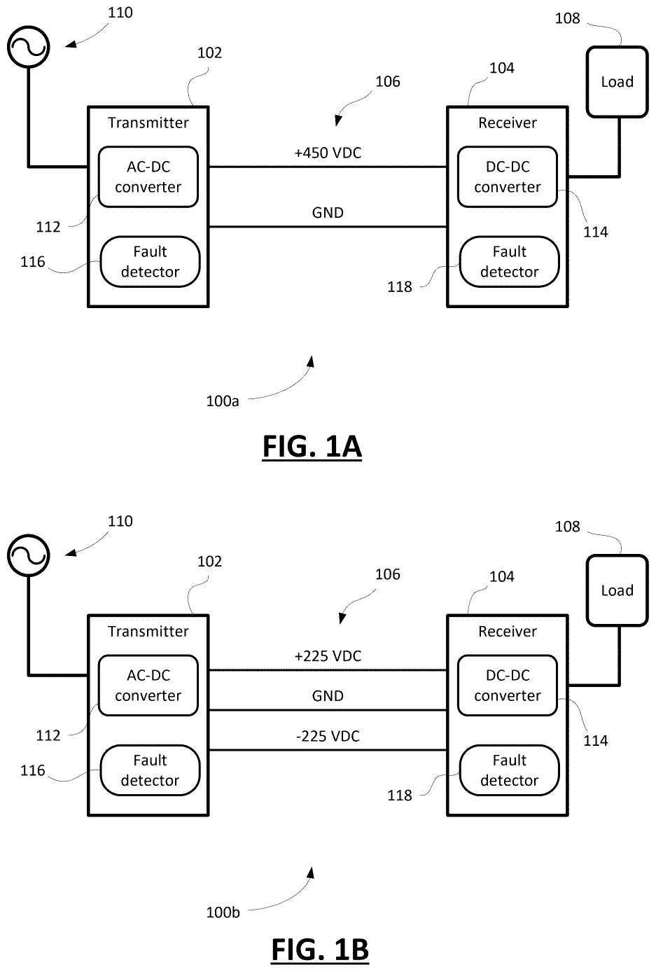

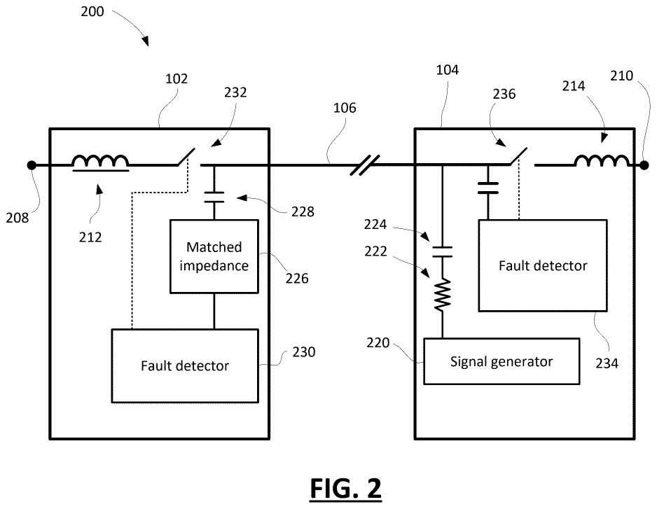

FIG. 1A diagrammatically illustrates an example of a basic DC power two-wire transmission system 100a. The system 100a includes a power transmitter 102 at one end of a transmission line 106 and a power receiver 104 at the other end of the transmission line 106. In some examples, the power receiver 104 may be a transceiver, enabling the chaining of successive transmission lines from transceiver to transceiver.

In this example, the receiver 104 is coupled to a DC load 108 and provides electrical power to the DC load 108. The transmitter 102 is connected to an AC power source 110, such as AC mains. The transmitter 102 may include a high-power AC-DC converter 112 configured to produce high-voltage DC power from the input AC power. In this example, the system 100a operates at +450 VDC. In this two-wire example, it will be noted that one wire is at ground and the other wire is at +VDC. The receiver 104 may include a DC-DC converter 114 to convert the +450 VDC to a load DC voltage level for the load 108, and a receiver VDC may be used internally at the receiver 104 for electronics and logic.

In this example, the transmitter 102 includes a transmitter fault detector 116 and the receiver includes a receiver fault detector 118. The fault detectors 116, 118 may be configured to quickly detect a fault on the transmission line 106, and in response to quickly disconnect the transmission line 106 from the AC power source 110 and to de-energize the transmission line 106.

FIG. 1B shows an example of a three-wire DC transmission system 100b. The three-wire DC transmission system 100b includes a transmission line 106 that features a ground wire, a positive DC voltage wire (e.g., +VDC wire) and a negative DC voltage wire (e.g., −VDC wire). In this example, the same DC voltage of +450 VDC is achieved, but through setting the positive wire to +225 VDC and setting the negative wire to −225 VDC.

As noted above, high speed fault detection is advantageous. Various UL standards, including UL 943 and UL1400-1, address the issue of fault-management.

Fault detection in electrical systems may sometimes employ residual current detection (RCD) as the mechanism for identifying a fault condition. In some instances, the RCD may have insufficient sensitivity to reliably generate a fault detection from a human touch. Increasing a number of turns of a live wire for detection can improve sensitivity but results in longer clearing time and a shock sensation. Typical ground-fault circuit interrupters may be too slow and may be better suited to AC fault detection.

At least one attempt has been made to carry out fault detection by sending a low-frequency pulsed signal from the power transmitter to the power receiver and determining, from measured reflections, a reflection coefficient and, thus, a normal impedance of the transmission line 106. A change in the measured impedance may signal a possible fault. This technique still ends up being too slow for effective quick fault detection and disconnection.

The present application describes a fast fault detection system and method for DC power. The system 100a, 100b exploits the skin effect for transmission lines 106. That is, at higher frequencies a current density of a signal is concentrated near a surface of an electrical conductor. As noted above, at higher frequencies, the human body can be modeled as a more complex impedance, including capacitive and inductive effects. The concentration of high frequency signals near the surface of a conductor makes those signals more susceptible to environmental influences, including contact with objects, particularly human or other living bodies. A touch event thus impacts a number of parameters that affect the high frequency signals propagating on a conductor.

An electrical conductor can be modelled as a wired channel having a transfer function that exhibits an impulse response h (t). The frequency response of such a channel may be expressed as:

$$H ( f ) = {\int }_{- ∞}^{+ ∞} h ( t ) {e}^{- j 2 π f t} dt$$

A fault, such as through the touch event, on the cable 106 is effectively a variation in the normal impulse response and corresponding frequency response of the cable 106.

In the present application, a high frequency signal is propagated from a receiving end of the cable 106 to the transmitting end. At the transmitting end, changes in the frequency response are detected by measuring an integral of a cross product of an original signal and a received signal. A significant variation may be indicative of a fault condition. In the case of a pure tone sinusoidal signal, produced by a sinusoidal generator, a magnitude of a frequency response on a single frequency may be estimated through monitoring an envelope of a power of the received signal. A significant change in the envelope may be indicative of a fault condition. Various filters may be used to eliminate non-fault conditions or transient false positives.

Using a periodic signal generator at the receiving end means that the fault detection system may further be leveraged to engage in a handshaking process prior to energizing the line 106 with high voltage DC power from a power source 110. This handshaking process when the system is initializing may improve the safety of the transmission line 106 through enabling use of an initial low voltage AC signal from the periodic signal generator to confirm the line is correctly connected and ready for high voltage energy and/or to detect faults at a lower DC voltage. This may eliminate or reduce the risk of high voltage arcs and/or faults.

The present system may further enable chaining of termination points, wherein the receiver 104 is constructed as a transceiver enabling the receiver 104 to serve as a receiver termination end for a first portion of the transmission line 106 and as a transmitter termination end for a subsequent portion of the transmission line 106. In an aspect, both ends of the transmission line 106 may each have a power transmitter 102 and a power receiver 104 thereby enabling a bidirectional power delivery.

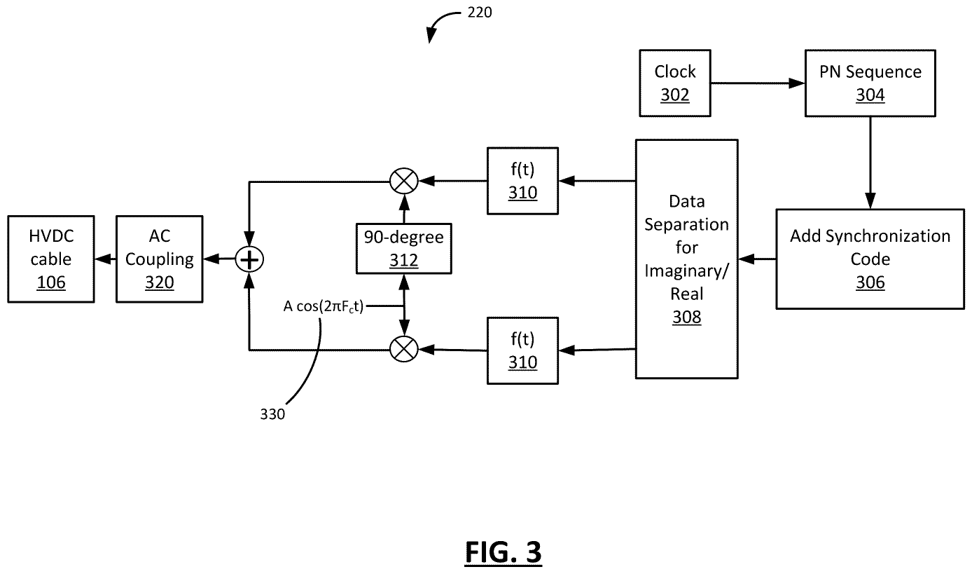

Reference is now made to FIG. 2, which shows one simplified example fault detection system 200 for DC power transmission. The system 200 in this example includes a transmitter 102 and a receiver 104 at respective ends of a transmission line 106. The transmission line 106 may be a two-wire cable in some implementations and may be a three-wire cable in some implementations. The system 200 is configured to connect a DC source 208 to a load 210. In some cases, the transmitter 102 may include power conversion components (not shown) to convert DC-to-DC and/or to convert AC-to-DC to realize the DC source 208. For example, the transmitter 102 may be connected to AC mains power through a single connection or multiple connections and may include one or more power converters to realize the DC source 208 for producing high voltage DC power. The DC source 208 may provide up to 450 VDC in some implementations. Other voltage levels may be used in other implementations.

In this example, the DC source 208 is coupled to the transmission line 106 through a source filter inductor 212 and the transmission line 106 is coupled to the load 210 through a load filter inductor 214. Other examples may comprise more complex filter types, such as an LC tank filter, and/or multiple order bandpass filters. The filter inductors 212, 214 may, in part, isolate the transmission line 106 from either the DC source 208 and/or the load 210. This may protect components of the DC source 208 and/or the load 210 from AC signals on the transmission line 106 and may isolate the transmission line 106 from interference signals generated within the DC source 208 and/or the load 210 that may hamper fault detection.

The system 200 is configured to quickly detect a fault condition. The system includes a signal generator 220 configured to generate a periodic signal at the receiver 104 in this example. The periodic signal may be a sinusoidal signal in some implementations. Although other periodic signals may be generated, such as sawtooth, square wave, or other such signals, many implementations may use a sinusoidal signal. In some cases, the sinusoidal signal may be a carrier signal that may be modulated by a code sequence. In some cases, as is described further below, the signal may be modulated. That is the signal generator 220 may generate a pseudo-noise code or pseudo-random-noise code, that is upconverted using a high frequency carrier signal. In some examples below, the signal generator 220 outputs a single tone sinusoid, i.e. an unmodulated high frequency carrier signal. The frequency of the signal may be between about 50-kHz and about 50-MHz.

The periodic signal may be significantly lower in amplitude than the high voltage DC power signal. In some examples, the DC power signal may be at about 450-VDC. The periodic signal in some implementations may be between about 5-V to about 40-V peak-to-peak.

The transmitter 202 may include a matched impedance 226 selected to closely match the impedance of the channel (e.g. the transmission line 206) to reduce or minimize reflected energy. In an ideal case, the matched impedance 226 ensures absorption of the periodic signal with little or no reflection. The matched impedance 226 may be coupled to the transmission line 106 through a blocking capacitor 228 to protect the matched impedance 226 and/or a fault detection circuit from the high voltage DC energy on the transmission line 106.

The transmitter 202 includes the fault detection circuit, which in this example includes a cross-correlation between the received signal and the reference signal. The fault detector 230 measures correlation between the periodic signal received after propagation through the transmission line 106 and a delayed version of the periodic signal transmitted. In particular, the cross-correlation change detector 230 detects a fault through detecting a change in the impulse response of the transmission line 206 by way of detecting a greater-than-threshold change in the autocorrelation.

The cross-correlation change detector 230 is coupled to a switch 232, which in this example is implemented using a MOSFET, and/or other disconnection circuitry that couples the DC source 208 to the transmission line 106. Other or additional circuit elements may be used to implement the switch. A current sensor (not shown) may be used for overcurrent protection. The disconnection circuitry may comprise line discharge circuitry at both the transmitter 102 and receiver 104 for discharging capacitance on the line when a fault is detected to discharge the transmission line 106. Discharging may include deenergizing the transmission line 106. In this aspect, when the cross-correlation change detector 230 detects a greater-than-threshold change in the impulse response of the transmission line 106, the detector 230 opens the switch 232 to disconnect the transmission line 106 from the DC power source 208. The discharge circuitry may comprise a discharge resistor to ground with a sufficient rating to dissipate the energy in the transmission line 106 as heat and/or light and/or avoid a risk of arcs, sparks, and/or other hazards. By discharging both ends of the cable 106, the speed with which the line 106 is de-energized may be improved.

In some implementations, the receiver 104 may also include a fault detector 234. The receiver-side fault detector 234 may be configured to detect reflections of the periodic signal. Under operating conditions, the matched impedance 226 may ensure that there are no significant reflections of the signal, such that the receiver-side fault detector 234 may expect no, or extremely small, high frequency signals. When a fault occurs on the line 106, the impedance of the transmission line 106 changes. Reflections may occur at the location of the fault, where an object in contact with the transmission line 106 may introduce an impedance that may cause reflection and impulse response variations that may generate distortion on the transmitted signal. The change in impedance of the transmission line 106 may result in a mismatch with the matched impedance 226, thereby resulting in reflected energy. The receiver-side fault detector 234 may be configured to detect a greater-than-threshold reflected energy under a fault condition and, in response, trigger a disconnection and discharge of the transmission line 106 at the receiver end.

In some implementations (not shown in FIG. 2), the transmitter 102 may include a separate periodic signal generator to propagate a signal towards the receiver 104. The fault detector 234 at the receiver 104 in such an aspect may be configured to operate in a manner similar to the cross-correlation change detector 230 by detecting a change in the frequency response based on the received high frequency signal at the receiver 104, such as from about 3-MHz to 30-MHz. Similar or the same techniques may apply to Very-High Frequency (VHF) bands and/or medium-frequency (MF) bands.

In some instances, a trade-off may be made between a speed and a reliability of the system 100, 200 based on a signal-to-noise ratio (SNR) of the transmission line 106. For example, a length of the transmission line 106 may alter the SNR on the transmission line 106 such that when the length of the transmission line 106 is short, a loss of the superimposed signal may be minimal thereby allowing the speed of response to be prioritized by adjusting one or more weights as described in further detail below. In another example, when the length of the transmission line 106 is long, the attenuation of the superimposed signal may be higher and therefore the signal-to-noise (SNR) is lower. In this instance, the speed of the response may be reduced to enhance robustness against false positives.

Particularly, for shorter cable lengths, an ohmic resistance of the transmission line 106 is lower, which increases the risk of electric shock. For example, a cable 106 with the ohmic resistance of 14-milliohms/meter, a current limit for a 10-meter cable is 400-V/(10-m*14-milliohms/m)=2857A. For a 1-km cable, the current limit is 400-V/(1000-m*14-milliohms/m)=28.57-A. The shorter cable may pose a higher risk due to the higher current limit than the longer cable where the current limit is significantly lower and discharges less current into an electrical fault (e.g. short circuit or human body contact).

As described herein, time domain signal processing techniques may be applied in detecting faults in the system 100, 200. The time domain signal processing techniques analyze one or more behaviors of the signals over time to identify any irregularities or faults within the system 100, 200. Through incorporating the cable length, the system may process the signal for additional time thereby increasing the processing gain to more effectively differentiate between normal and faulty signals. By extending the time for the signal analysis, the system 100, 200 may selectively detect faults and/or deviations and therefore overall fault detection accuracy and system reliability.

A fault may be detected due to a multiplication of a fault signal with specific characteristics onto the original signal that is sent by the signal generator 220 through the cable 106. This signal can be modeled by the following mathematical relation called a fault function:

$$g ( t ) = \{ \begin{matrix}1 & , t \leq 0 \\ 1 - γ t & , 0 < t \leq {T}_{f} \\ 1 - γ {T}_{f} & , {T}_{f} < t\end{matrix}$$

where γ represents a change (e.g. delta) in an amplitude of the original signal in a presence of an electrical fault on the cable 106 and demonstrates how the fault is affecting the line 106; Tris a falling time (ΔT). For example, a short circuit fault may have a maximum value of a which is 1 and a touch fault (e.g. human skin contact) is between about 0.01 to about 0.05 (e.g. up to 5% variations). Thus, short circuit faults are much easier to detect.

The Fourier domain representation of the above function can be calculated as follows:

$$G ( f ) = {\int }_{- ∞}^{+ ∞} g ( t ) {e}^{- j 2 π f t} dt$$

which results in:

$$G ( f ) = {\int }_{- ∞}^{0} {e}^{- j 2 π f t} dt + {\int }_{0}^{{T}_{f}} ( 1 - γ t ) {e}^{- j 2 π f t} dt + {\int }_{{T}_{f}}^{+ ∞} ( 1 - γ {T}_{f} ) {e}^{- j 2 π f t} dt ,$$

The first part of the above equation may be simplified as follows:

$${\int }_{- ∞}^{0} {e}^{- j 2 π f t} dt = - \frac{1}{j 2 π f}$$

The second part of the previous equation can be simplified as follows:

$${\int }_{0}^{{T}_{f}} ( 1 - γ t ) {e}^{- j 2 π f t} dt = {\int }_{0}^{{T}_{f}} {e}^{- j 2 π f t} dt - {\int }_{0}^{{T}_{f}} γ {te}^{- j 2 π f t} dt = - \frac{1}{j 2 π f} ( {e}^{- j 2 π {fT}_{f}} - 1 ) - {\int }_{0}^{{T}_{f}} α {te}^{- j 2 π f t} dt$$

By setting u=t and dv=e^{-j2πft} dt results in:

$$\int udv = uv - \int vdu$$

and therefore:

$${\int }_{0}^{{T}_{f}} γ {te}^{- j 2 π f t} dt = γ {\int }_{0}^{{T}_{f}} {te}^{- j 2 π f t} dt = γ ( \frac{{T}_{f} {e}^{- i 2 π {fT}_{f}}}{- j 2 π f} + \frac{1 - {e}^{- j 2 π {fT}_{f}}}{- 4 {π}^{2} {f}^{2}} )$$

The Fourier representation of the fault event function is as follows:

$$G ( f ) = \frac{1}{j 2 π f} + ( \frac{1 - {e}^{- j 2 π {fT}_{f}}}{j 2 π f} - γ ( \frac{{T}_{f} {e}^{- j 2 π {fT}_{f}}}{- j 2 π f} + \frac{1 - {e}^{- j 2 π {fT}_{f}}}{- 4 {π}^{2} {f}^{2}} ) + \frac{( 1 - γ {T}_{f} ) {e}^{- j 2 π {fT}_{f}}}{j 2 π f} )$$

Fault events contain high-frequency components and may be detected using a limited bandwidth, which reduces the speed of the fault detection system 100, 200. As described herein, a structure of the power transmitter 102 in the fault detection system 100, 200 may be adaptive by using multiple filter structures 520, 620 with varying bandwidths to achieve different reaction times based on low or high frequency components of the Fourier transform of the fault function. The multiple filter structures 520, 620 may each be tailored to a specific bandwidth. These filters 520, 620 may operate across different bandwidth values and adapt the response based on the characteristics of the fault.

When the system 100, 200 limits the bandwidth to reduce the effect of noise or for other operational reasons, an ability to detect rapid faults may be compromised (e.g. the system automatically trades off response time with accuracy based on evaluation of SNR). The transmitter 102 in the fault detection system 100, 200 may have an adaptive architecture. For example, wide-bandwidth filters may capture the high-frequency components thereby enabling faster fault detection but at a cost of increased noise sensitivity. Narrow-bandwidth filters focus on lower frequencies thereby providing a more stable and noise-resistant operation but slower fault detection for rapidly occurring events.

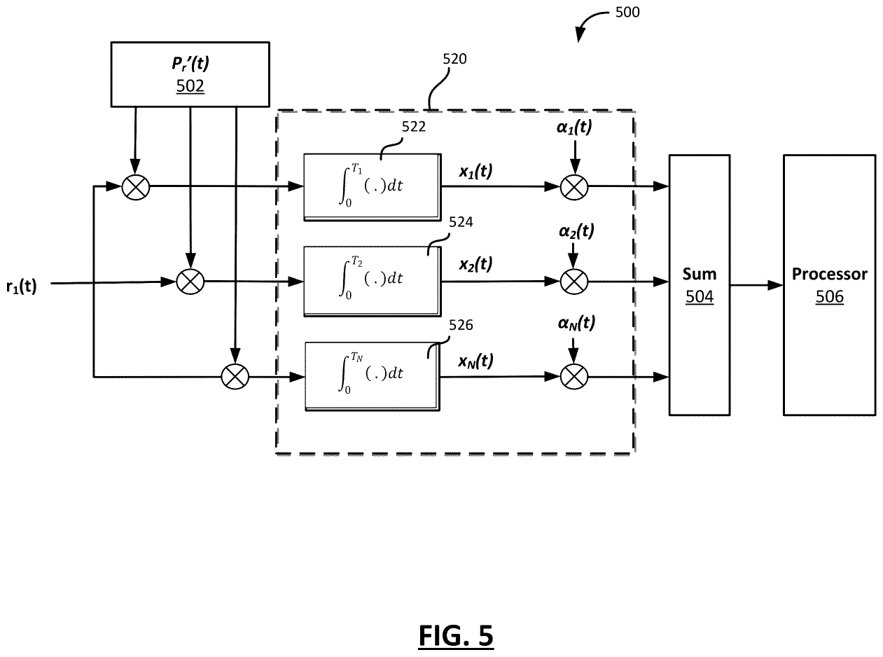

By adjusting one or more weights at the output of filter branches, the system 100, 200 may optimize performance as described in further detail below with reference to FIGS. 4 to 6. The output of higher-bandwidth filters may be noisier than that of lower-bandwidth filters resulting in lower signal-to-noise ratios for the higher-bandwidth branches compared to the lower-bandwidth branches. In the aspects herein, lower weights may be applied at the output of the higher-bandwidth filters and higher coefficient values at the output of the lower-bandwidth filters. When a fault event, like a short circuit, occurs, the value of γ may become high, allowing the high-bandwidth filters with low weights to have a significant impact on the output of the summation block. For low values of γ, only the low-bandwidth filters with higher coefficients may substantially affect the summation block output. The adaptive weights may allow the system 100, 200 to respond quickly to faults that occur with high-frequency characteristics (such as sudden changes like short-circuit) while maintaining stability by reducing susceptibility to false detections during operation.

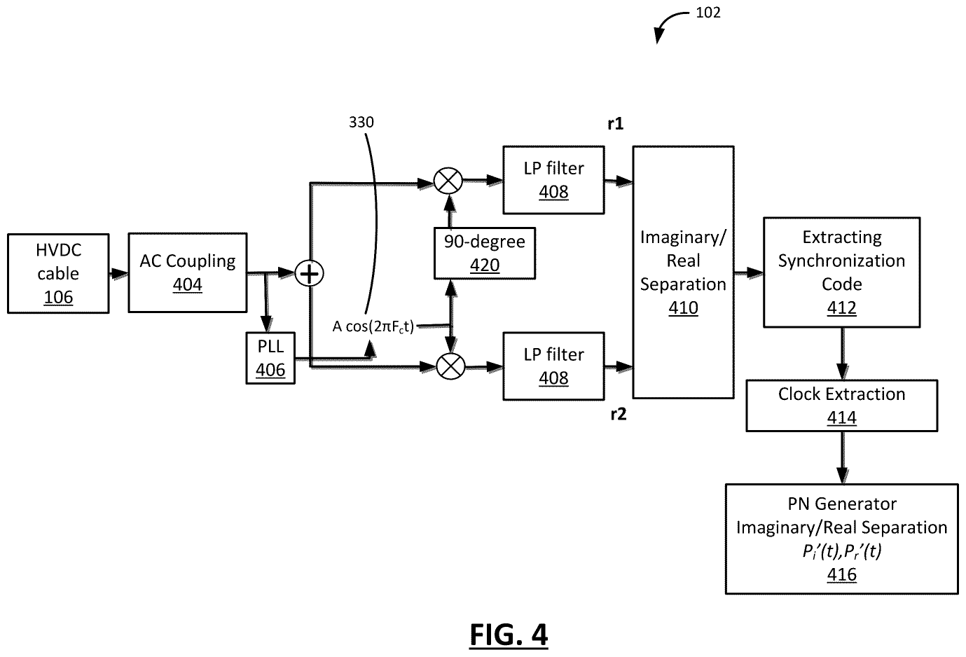

Turning to FIG. 3, the power receiver 104 may comprise the signal generator 220. In this aspect, the receiver 104 uses a spread spectrum signal or a pure tone signal to monitor a variation of cable impulse response in a specific bandwidth or at a single frequency, respectively. A clock 302 drives a pseudorandom number sequence generator 304 (e.g., PN sequence generator) for generating a deterministic signal. The PN sequence may have a length with a chip time of 0<T_{c}≤∞. In the case of T_{c}=∞, the PN sequence may be a constant value (e.g., non-varying). The chip time may be a duration of an element in the code for code-division multiple access (CDMA). For lower values of T_{c}, the signal bandwidth may be higher and the system 100, 200 may monitor higher bandwidths of the cable 106 to check for impedance variations. The injected signal may have characteristics such that the correlation of the signal with a delayed copy of itself (also known as autocorrelation) is low. Suitable candidates for this type of signal may include a random sequence such as a Barker code, or a binary Alexis sequence, as examples.

The use of spread spectrum techniques may reduce interference between different pairs of power transmitters 102 sending power through different pairs of cables 106, bundled in a single jacket or the interference that may be generated by radio frequency interference sources (e.g. radios, motors, etc.) transmitting close to the system 100, 200. Some methods for generating these PN codes may include: one or more Pseudorandom Number Generators (PRNGs), Gold Codes, and/or Kasami Codes. The PRNG may generate long sequences of bits that appear random but are deterministically produced. Examples include Linear Feedback Shift Registers (LFSRs) that may be used to create long, repeatable codes with good statistical properties. The Gold Codes may be a family of sequences generated from two polynomials using LFSRs. The Gold Codes may have good cross-correlation properties suitable for fault detection applications as described herein. The Kasami Codes may be a set of sequences with low cross-correlation properties and may be used in high-interference resistance applications.

A synchronization code generator 306 may add a synchronization code to the PN sequence. The synchronization code 306 may enable the power transmitter 102 to synchronize with the signal transmitted by the signal generator 220. A data separation 308 may be performed to separate imaginary and real components of the synchronized PN sequence. The real component and the imaginary component may be pass through a shaping filter 310 to remove out of band harmonics that may be generated by a digital-to-analog converter (not shown) within the PN generator 304 and/or the synchronization code generator 306.

The in-phase component and the quadrature component may be modulated with a carrier signal 330 represented by A cos (2πF_{c}t) produced by a signal generator (not shown). The output of the signal generator may be a periodic signal with a peak-to-peak amplitude of about 1.2-V. An amplifier (not shown) may increase the amplitude of the carrier signal 330 to about 12-V peak-to-peak. In other aspects, other voltage levels may be used. In some aspects, the transmission line 106 may operate at, at least 300-VDC and the carrier signal 330 may have a peak-to-peak amplitude of between about 10-V to about 24-V. In some aspects, the transmission line 106 may operate at any DC level at or above +60-VDC. The in-phase component may be modulated by the cosine whereas the quadrature component may be modulated by a phase-shifted 312 cosine (i.e., sine). The two modulated components are then combined into a fault detection signal and passed through an AC coupling 320 to the High Voltage Direct Current (HVDC) cable 106 for transmission to the power transmitter 102.

Turning to FIG. 4, the HVDC cable 106 passes the fault detection signal to the power transmitter 102 (also known as the fault detection receiver). The fault detection signal passes through an AC coupling 404 that isolates the fault detection signal from the high-voltage DC component. A phase-lock loop 406 synchronizes with the synchronization code to lock on the received modulation signal 330. In other aspects, other techniques may be used to lock onto the modulation signal 330, such as a Costas loop, a frequency-locked loop, a carrier recovery circuit, a direct digital synthesis, and/or an automatic frequency control. A code signal P(t) is used to modulate a carrier frequency A cos (2πf_{c}t). The modulated signal 330 passes through the cable having a time variant frequency response. At the power transmitter end of the system 102, a phase-locked loop 406 is used to extract the carrier signal and to use the carrier signal to demodulate the received signal to recover P′(t). Based on cross-correlation between the transmitted sequence and the received sequence, P(t) and P′(t), the system tracks the impulse response, which is the channel frequency response in the frequency domain.

In some aspects, the phase-locked loop 406 may be removed when a single frequency signal is used. In this instance, the received signal is mixed with itself, A(t) cos (2πf_{c}t), where the value of A(t) is related to the frequency response of the cable at the specific carrier frequency.

The modulation signal 330 may be used to demodulate the synchronization code from the carrier signal. The demodulated synchronization code may pass through a pair of low-pass filters 408 to remove any out of band noise. The real component and the imaginary component may be separated 410 and a synchronization code extractor 412 may provide the synchronization code. A clock may be extracted by a clock extractor 414. A PN generator 416 may generate the real component and the imaginary component of the PN sequence.

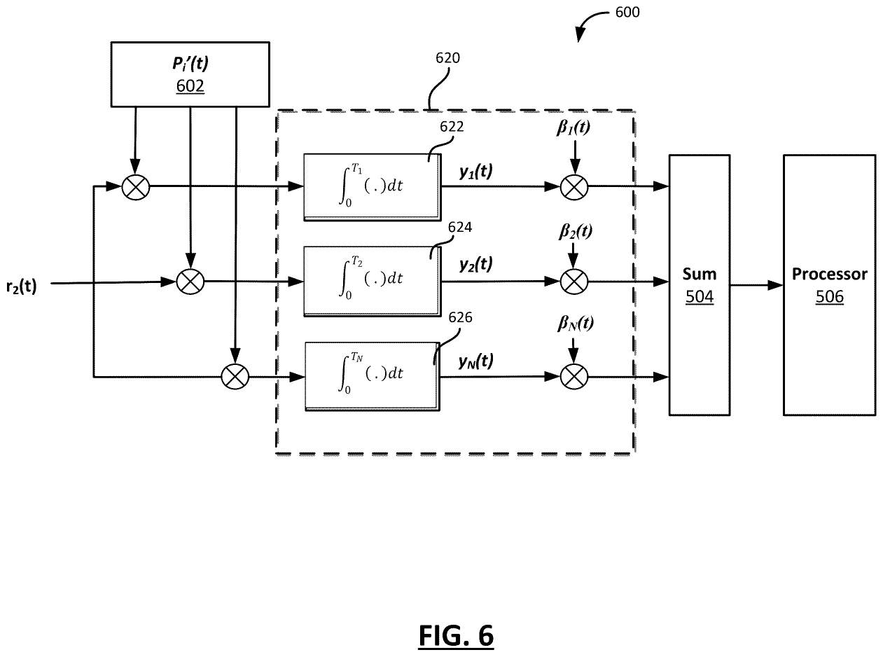

With reference to FIGS. 5 and 6, the PN generator 416 may comprise a real processor component 500 and an imaginary processor 600. The one or more filter branches 520, 620 may detect different faults within the cable 106. Each of the branches may be different in respect to a fault detection speed and a signal-to-noise ratio (SNR).

As previously mentioned, the power transmitter 102 may, after receiving the signal, synchronize the original pseudo-noise (PN) sequence with the receiver 104. The synchronization allows the transmitter 102 and receiver 104 to align their signal patterns and operate in unison. Once synchronization is achieved, the transmitter 102 processes the real component of received signal into multiple branches 520 and the imaginary component of the received signal into multiple branches 620. Each branch 520, 620 may process the received signal with a real set of integrators 522, 524, 526 and an imaginary set of integrators 622, 624, 626 with a distinct time constant, denoted as T₁, T₂, . . . , T_{N}.

Each of the in-phase and quadrature sets of integrators accumulate the received signal over time thereby smoothing out fluctuations and emphasizing the overall signal trend. The time constant, Tᵢ, in each branch may determine how long the integrator “remembers” the past received signal. A higher time constant causes the integrator to average the received signal over a longer period. A larger integration time constant increases a system robustness against noise through noise averaging. Noise and/or interference tend to fluctuate rapidly. By integrating the received signal over a longer time period, the integrator averages out short-term fluctuations caused by the noise. This reduces an impact of the noise and provides a cleaner signal output.

The higher time constant results in a slower system response to electrical faults. While the system 100, 200 becomes more robust against noise, the system 100, 200 also becomes less responsive to fast changes in the received signal caused by electrical faults. The smoothing effect may suppress high-frequency components of the received signal, particularly in dynamic or rapidly changing environments.

The use of multiple branches 520, 620, each with a different integration time constant, may allow the fault detection system 100, 200 to adapt to various signal conditions. By applying different time constants for each branch 520, 620, the system 100, 200 may balance noise resistance and responsiveness. Shorter time constants in some branches 520, 620 may provide faster reaction times to sudden changes in the received signal. These branches 520, 620 may be more sensitive to different fault conditions, such as high-frequency components and could detect anomalies, faults, or rapid changes. Longer time constants in other branches 520, 620 may filter out noise more effectively than the short time constant branches 520, 620 and focus on a steady-state or long-term behavior of the received signal.

The multiple branches 520, 620 may provide adaptive signal processing by weighting branches 520, 620 based on a signal environment. In this aspect, one or more weights (e.g. gains), a, B, for the branches 520, 620 may be adjusted based at least on a signal-to-noise ratio (SNR) of the transmission line 106. For example, in a noisy environment, the branches 520, 620 with longer time constants may have a higher weight and as such may dominate. Whereas in a clean signal environment, the branches 520, 620 may have their weights reduced and branches 520, 620 with shorter time constants may have their weights increased to detect rapid events. In some aspects, one or more of the branches 520, 620 may be disabled by setting the weights to a value of zero.

One or more of the branches 520, 620 may be directed to changes in the frequency response of the cable 106 caused by a number of possible events, such as environmental changes or physical movement of the cable 106. For example, even small physical disturbances that do not amount to touch events, such as an object pressing on the cable 106, wind events, and the like, can alter the physical characteristics of the cable 106 and the spacing between conductors. A true electrical fault caused by, for instance, a human or animal skin touch event, causes a rapid change in the frequency response and, accordingly, the power signal envelope. Mechanical events, like vibrations, compression, and other physical adjustments to the cable 106, such as variation in conductor spacing, tend to occur over a slower timeline. The slower rate of a physical event means that the resultant change in the frequency response and, thus, the change in the power signal envelope, is much slower than in the case of an electrical fault. One or more of the branches 520, 620 may be directed to determining one or more of these incidents.

When the sequence at the receiver 104 and transmitter 102 matches, the integration operation on the down-converted version of the received signal may be as follows:

$${x}_{i} = {\int }_{0}^{{T}_{i}} {r}_{1} ( t ) {P}_{r}^{′} ( t ) dt = {\int }_{0}^{{T}_{i}} ( {AP}_{r}^{′} ( t ) + n ( t ) ) {P}_{r}^{′} ( t ) dt = {\int }_{0}^{{T}_{i}} ( A + n ( t ) {P}_{r}^{′} ( t ) ) dt$$

where r₁ is the quadrature component and r₂ is the in-phase component of the down-converted signal as shown particularly in FIGS. 5 and 6 respectively. The above integral equation may be approximated by following summation relation:

$${x}_{i} = {\int }_{0}^{{T}_{i}} ( A + n ( t ) {P}_{r}^{′} ( t ) ) dt \approx {\sum }_{j} ( A + {n}^{′} ( j Δ t ) ) Δ t , 1 \leq j \leq \frac{{T}_{i}}{Δ t}$$

The above equation may be simplified as follows:

$${x}_{i} \approx {AT}_{i} + {\sum }_{j} {n}^{′} ( j Δ t ) , 0 \leq j \leq \frac{{T}_{i}}{Δ t}$$

The above equation comprises a constant term that is a function of the transmitted signal amplitude, which may be used to monitor and/or detect electrical faults. The second, time-varying term may vary with electrical noise. The second term may be replaced by a single random variable which represents the noise.

When n(t) is Gaussian random variable and Pᵢ(t), Pᵣ(t)∈{−1,1}, n′(jΔt) is also a Gaussian random variable with a zero mean and a same variance of n(t). When Δt is selected such that Δt is below the value of 1/2BW where BW is the bandwidth of the noise, then Σᵢn′(jΔt) is a Gaussian random variable with the variance of

$$\frac{{T}_{j}}{Δ t} {σ}_{n}^{2} .$$

The signal to noise ratio at j-th branch of the transmitter 102 may be:

$${SNR}_{i} = \frac{{( {AT}_{i} )}^{2}}{\frac{{T}_{i}}{Δ t} {σ}_{n}^{2}} = \frac{{A}^{2}}{{σ}_{n}^{2}} {T}_{i} Δ t = {SNR}^{*} {T}_{i} Δ t ,$$

Replacing Δt with 1/2BW we have:

$${SNR}_{i} = \frac{{SNR}^{*} {T}_{i}}{2 BW}$$

The value of SNR* may represent a fundamental signal-to-noise ratio for one snapshot of the received signal which may be improved by the value of Tᵢ. Therefore, the signal to noise ratio can be improved by the coefficient of the

$$\frac{{SNR}^{*} {T}_{i}}{2 BW}$$

term.

The mutual information between the transmitted signal and the received signal can be simplified as follows:

$$I ( {r}_{1} ( t ) ; {x}_{i} ( t ) ) = h ( {x}_{i} ( t ) ) - h ( {x}_{i} ( t ) \vert {r}_{1} ( t ) ) = \frac{1}{2} {log}_{2} 2 π e {σ}_{{x}_{i}}^{2} - \frac{1}{2} {log}_{2} 2 π e {σ}_{{n}^{″}}^{2}$$

where in the above relation,

$${σ}_{{x}_{i}}^{2}$$

is the variance of the received signal plus noise, which is assumed to be a Gaussian random process; h(⋅) is the differential entropy of a random variable. Therefore,

$${σ}_{{x}_{i}}^{2}$$

has two components of which one is the noise term variance of

$${σ}_{{n}^{″}}^{2} = \frac{{T}_{i}}{Δ t} {σ}_{n}^{2}$$

and the other one is the signal power which is (ATᵢ)². The above relation can be simplified as follows:

$$I ( {r}_{1} ( t ) ; {x}_{i} ( t ) ) = \frac{1}{2} {log}_{2} 2 π e ( {( {AT}_{i} )}^{2} + {σ}_{{n}^{″}}^{2} ) - \frac{1}{2} {log}_{2} 2 π e ( {σ}_{{n}^{″}}^{2} ) = \frac{1}{2} {log}_{2} 2 π e ( {( {AT}_{i} )}^{2} + {σ}_{{n}^{″}}^{2} ) - \frac{1}{2} {log}_{2} 2 π e ( {σ}_{{n}^{″}}^{2} ) = \frac{1}{2} {log}_{2} ( 1 + \frac{{( {AT}_{i} )}^{2}}{{σ}_{{n}^{″}}^{2}} ) = \frac{1}{2} {log}_{2} ( 1 + \frac{{SNR}^{*} {T}_{i}}{2 BW} ) bits$$

Using a similar process for finding mutual information between r₂(t) and yᵢ(t), as follows:

$$I ( {r}_{2} ( t ) ; {y}_{i} ( t ) ) = \frac{1}{2} {log}_{2} 2 π e ( {( {AT}_{i} )}^{2} + {σ}_{{n}^{″}}^{2} ) - \frac{1}{2} {log}_{2} 2 π e ( {σ}_{{n}^{″}}^{2} ) = \frac{1}{2} {log}_{2} ( 1 + \frac{{( {AT}_{i} )}^{2}}{\frac{{T}_{i}}{Δ t} {σ}_{n}^{2}} ) bits = \frac{1}{2} {log}_{2} ( 1 + \frac{{SNR}^{*} {T}_{i}}{2 BW} ) bits$$

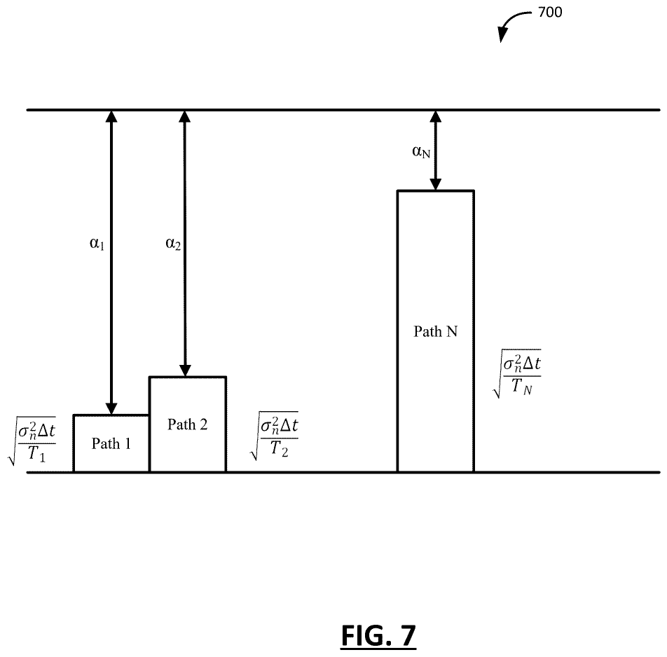

The mutual information between the fault event and the received weighted sum value of the different branches can be maximized by finding proper values for α₁, . . . , α_{N} and β₁, . . . , β_{N}. Both α₁, . . . , α_{N} and β₁, . . . , β_{N} may be calculated with a similar approach. When Tᵢ>>Tᵢ₊₁, then x; (t), 1≤i≤N and the additive noise term of each path is independent from each other, where these additive noise terms are independent with different noise power level. Referring to FIG. 7, the noise power of each path is

$$\frac{{σ}_{n}^{2}}{2 {BWT}_{i}} .$$

Using the water filling technique, the value of αᵢ (coefficient value) may be optimized based on the water filling theorem as follows:

$${α}_{i} = cte - \sqrt{\frac{{σ}_{n}^{2}}{2 {BWT}_{i}}}$$

where cte is a constant value and depends on a dynamic range of the amplifiers and digital parts of the system. After combining the above signals, one can find the fault by monitoring the variation of the output power for fault events.

The noise power at the output of each branch can be calculated using a simple variance detector circuit or an algorithm in a basic microcontroller.

Once xᵢ(t), yᵢ(t), αᵢ, and βᵢ have been determined, each of the branches may be summed by a summation 504 and the sum may be received by a processor 506 for further analysis.

The variation of the weighted sum of the branches 520, 620 may be compared to a threshold value and/or threshold signal to determine whether a fault condition exists. For example, a comparator may be used to compare the filtered rate-of-change signal to a threshold signal and the comparator may output a fault signal indicating a fault when the filtered rate-of-change signal indicates a sufficiently significant change in the RMS power envelope of the injected signal. Other aspects may use the processor 506 to perform this analysis.

The threshold signal input to the comparator 622 may not be a fixed threshold but may be varied slightly over time using a variance detector executing by the processor 506. The variance detector may be configured to dynamically adjust the threshold signal to account for the fact that the environment may have changing RF noise and other artefacts. In some aspects, gradual adjustments to sensitivity of the fault detection and/or the threshold signal may be performed.

According to another aspect, the PN sequence generator 304 may be simplified by sending a constant value signal (e.g. single tone signal) at a specific frequency where cable loss is minimal while still maintaining sensitivity to fault events. The block 306 responsible for adding the synchronization code may also be removed. In this instance, the constant value signal may be monitored for the variation of this signal to detect faults. The integrator in different branches 520, 620 may be replaced by filters with varying and/or adjustable bandwidths. A higher value of Tᵢ corresponds to a narrower bandwidth, allowing for more detailed frequency analysis, while a lower value of Tᵢ results in a wider bandwidth.

Narrow bandwidth filters may isolate specific frequency components to identify subtle signal changes, such as those caused by small faults or disturbances. A lower Tᵢ leads to a wider bandwidth, which allows higher frequencies to pass through the filter for scenarios where a broader range of signal components is to be analyzed and/or where high precision in frequency discrimination is not required.

As implementing narrow bandwidth filters at high frequencies may be challenging (e.g. filters with high Q-factors), the original signal may be down-converted to a lower frequency.

Although the aspects herein may demonstrate discrete components, such as a discrete signal generator, other aspects may have one or more of the components implemented in a programmed microcontroller. The microcontroller may be replaced with an application-specific integrated circuit (ASIC), digital signal processor, and/or another form of digital controller for controlling operation. In some aspects, the microcontroller may receive signals from the receiver-side fault detection circuitry. In some aspects, the microcontroller may be configured to control discharge of the line 106, output notification signals, and/or engage in a handshake process prior to energizing of the transmission line 106. In this example, the microcontroller may be configured to set the frequency of the periodic signal generated by the signal generator. In some cases, the microcontroller may be configured to output the PN code that may be upconverted by mixing with the sinusoidal carrier signal generated by the signal generator.

The signal generator may be coupled to the transmission line through a series resistor and a blocking capacitor. The series resistor may serve as an impedance matching resistor and may modify the series cable resistance to improve sensitivity of the touch detection.

The above-described system may be implemented in a way that achieves high speed detection of a fault condition, high speed disconnection, and/or discharge of the transmission line 106. While other fault detection apparatuses may take as little as 1-3 milliseconds to detect a fault condition, the present application describes apparatuses that can detect a fault condition within microseconds.

It will be appreciated that it may be that some or all the above-described operations of the various above-described example methods may be performed in orders other than those illustrated and/or may be performed concurrently without varying the overall operation of those methods. It will also be appreciated that some or all the above-described operations of the various above-described example methods may be performed in response to other above-described operations.

It will be understood that the applications, modules, routines, processes, threads, or other software components implementing the described method/process may be realized using computer programming techniques and languages. The present application is not limited to particular processors, computer languages, computer programming conventions, data structures, or other such implementation details. Those skilled in the art will recognize that the described processes may be implemented as a part of computer-executable code stored in volatile or non-volatile memory, as part of an application-specific integrated chip (ASIC), etc.

Adaptations and modifications of the described aspects can be made. Therefore, the above discussed aspects are illustrative and not restrictive.

1. A fault detection system for detecting a fault condition in a direct current (DC) system, the system comprising:
a power transmitter to energize a cable with electrical power;
a power receiver connected to the cable providing the electrical power to a load; and
at the power receiver, a signal generator coupled to the cable to generate and propagate a deterministic signal on the cable,
at the power transmitter,
a fault detector coupled to the cable to receive a received signal comprising the deterministic signal and noise after propagation through the cable,
the fault detector comprising a plurality of filter branches,
the filter branches having an associated bandwidth filtering the received signal, and
a disconnection circuitry discharging the cable when a fault is detected on at least one of the filter branches.

2. The fault detection system of claim 1, wherein the signal generator comprises a pseudorandom number sequence generator and the deterministic signal comprises at least a pseudorandom number sequence.

3. The fault detection system of claim 2, wherein the pseudorandom number sequence is selected from: a Barker code, a binary Alexis sequence, a Gold code, and a Kasami code.

4. The fault detection system of claim 1, wherein the signal generator comprises a synchronization code generator adding a synchronization code to the deterministic signal.

5. The fault detection system of claim 1, wherein the signal generator comprises a modulator modulating a carrier signal with the deterministic signal.

6. The fault detection system of claim 5, wherein the fault detector comprises a phase-locked loop to lock onto the carrier signal.

7. The fault detection system of claim 1, wherein the fault is detected based on a summation of an output of the filter branches.

8. The fault detection system of claim 1, further comprises a processor configured to adjust at least one weight for at least one of the filter branches.

9. The fault detection system of claim 8, wherein the at least one weight is adjusted based at least on a signal-to-noise ratio at an input of the fault detector.

10. The fault detection system of claim 1, wherein the signal generator comprises a sinusoidal generator and the deterministic signal comprises a sinusoid at a frequency.

11. A fault detection method for detecting a fault condition in a direct current (DC) system, the method comprising:
energizing a cable from a power transmitter to a power receiver;
providing electrical power to a load;
generating and propagating a deterministic signal on the cable from the power receiver to the power transmitter;
receiving a received signal comprising the deterministic signal and noise at the power transmitter and passing the received signal through a plurality of filter branches, the filter branches having an associated bandwidth filtering the received signal;
detecting a fault from at least one of the filter branches; and
discharging the cable when the fault is detected.

12. The fault detection method of claim 11, wherein generating the deterministic signal comprises at least a pseudorandom number sequence.

13. The fault detection method of claim 12, wherein the pseudorandom number sequence is selected from: a Barker code, a binary Alexis sequence, a Gold code, and a Kasami code.

14. The fault detection method of claim 11, wherein generating the deterministic signal comprises adding a synchronization code to the deterministic signal.

15. The fault detection method of claim 11, further generating the deterministic signal comprises modulating a carrier signal with the deterministic signal.

16. The fault detection method of claim 15, further comprising locking onto the carrier signal with a phase-locked loop at the power transmitter.

17. The fault detection method of claim 11, further comprising summing an output of the filter branches to detect the fault.

18. The fault detection method of claim 11, further comprising adjusting at least one weight on at least one of the filter branches.

19. The fault detection method of claim 18, further comprising adjusting the weight on the at least one of the filter branches based on at least a signal-to-noise ratio of the received signal.

20. The fault detection method of claim 11, wherein the deterministic signal comprises a sinusoid at a frequency.
